(19) United States
(12) Patent Application Publication
(10) Pub. No.: US 2016/0174410 A1
(43) Pub. Date: Jun. 16, 2016

(54) HEAT DISSIPATION DEVICE AND HEAT DISSIPATION SYSTEM

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventors: HAI-YUN WANG, Wuhan (CN); LING CEN, Wuhan (CN); XU LI, Wuhan (CN)

(21) Appl. No.: 14/593,156

(22) Filed: Jan. 9, 2015

(30) Foreign Application Priority Data
Dec. 12, 2014 (CN) 201410760726.5

(51) Int. Cl. H05K 7/20

(52) U.S. Cl. CPC H05K 7/20136

(57) ABSTRACT

A heat dissipation device includes a first heat dissipation member, a second heat dissipation member, and a heat conduction member. The heat conduction member can be U-shaped. The first heat dissipation member and the second heat dissipation member are located on two ends of the heat conduction member. The two ends of the heat conduction member are substantially parallel to each other. One end of the heat conduction member is engaged with a heating element and conducts heat to the first heat dissipation member and the second heat dissipation member. A heat dissipation system with the heat dissipation device is also provided.

### CROSS-REFERENCE TO RELATED APPLICATIONS

This application claims priority to Chinese Patent Application No. 201410760726.5 filed on Dec. 12, 2014, the contents of which are incorporated by reference herein.

### FIELD

The subject matter herein generally relates to a heat dissipation device.

### BACKGROUND

When electronic devices are in a working state, the circuits and the microprocessors can generate heat. If the heat is not reduced in time, the electronic devices will be damaged.

### BRIEF DESCRIPTION OF THE DRAWINGS

Implementations of the present technology will now be described, by way of example only, with reference to the attached figures.

FIG. 1 is an exploded, isometric view of one embodiment of a heat dissipation device.

FIG. 2 is an assembled, isometric view of the heat dissipation device of FIG. 1.

FIG. 3 is similar to FIG. 2, but viewed from another angle.

FIG. 4 is a partly assembled, isometric view of one embodiment of a heat dissipation system.

FIG. 5 is an assembled, isometric view of the heat dissipation system of FIG. 4.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

The present disclosure is described in relation to a heat dissipation device.

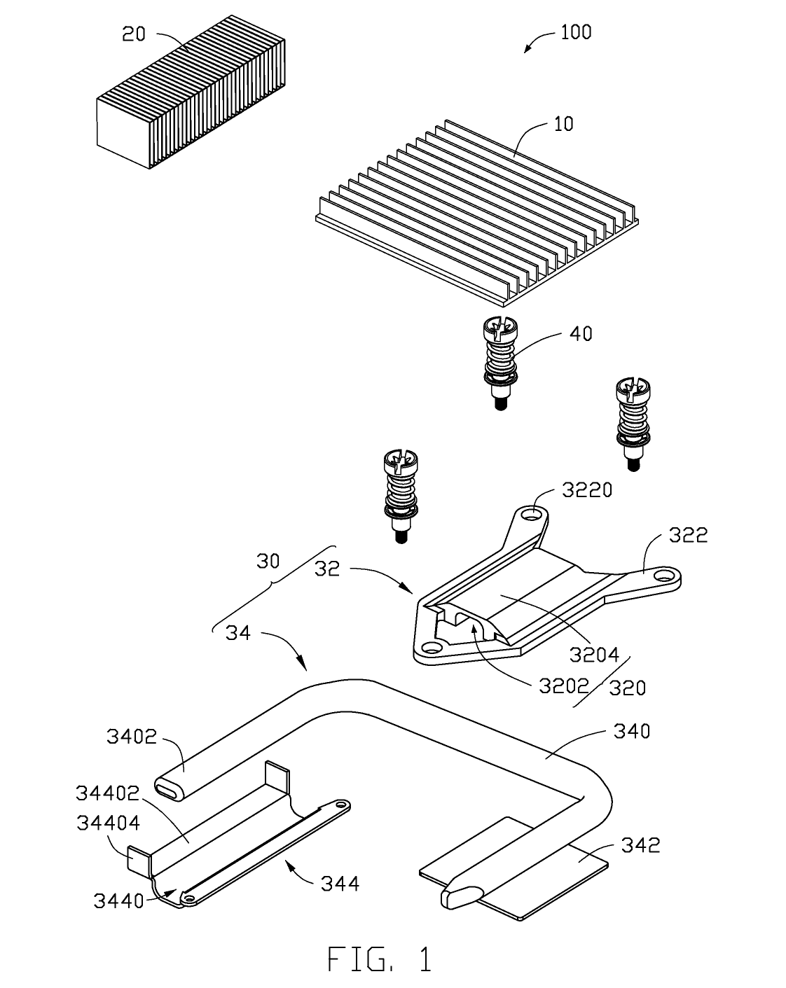

FIG. 1 illustrates one embodiment of a heat dissipation device 100. The heat dissipation device 100 includes a first heat dissipation member 10, a second heat dissipation member 20, a heat conduction member 30, and a plurality of screws 40.

The heat conduction member 30 includes a first heat conduction member 32 and a second heat conduction member 34. The first heat conduction member 32 includes a plate 320 and three fixing portions 322. The three fixing portions 322 extend from the plate 320. The plate 320 defines a slot 3202 and includes a plane 3204. Each fixing portion 322 defines a hole 3220. The second heat conduction member 34 includes a body 340, a heat exchanging plate 342, and a connecting member 344. The connecting member 344 includes a mounting plate 34402 and two stopper plates 34404. The connecting member 344 defines a groove 3440. The two stopper plates 34404 extend from two opposite ends of the mounting plate 34402. The two stopper plates 34404 are substantially parallel to each other. Each stopper plate 34404 is substantially perpendicular to the mounting plate 34402. The groove 3440 is located on one side of the mounting plate 34402. In at least one embodiment, the body 340 can be substantially U-shaped and include two pipes 3402. Two pipes 3402 are substantially parallel to each other.

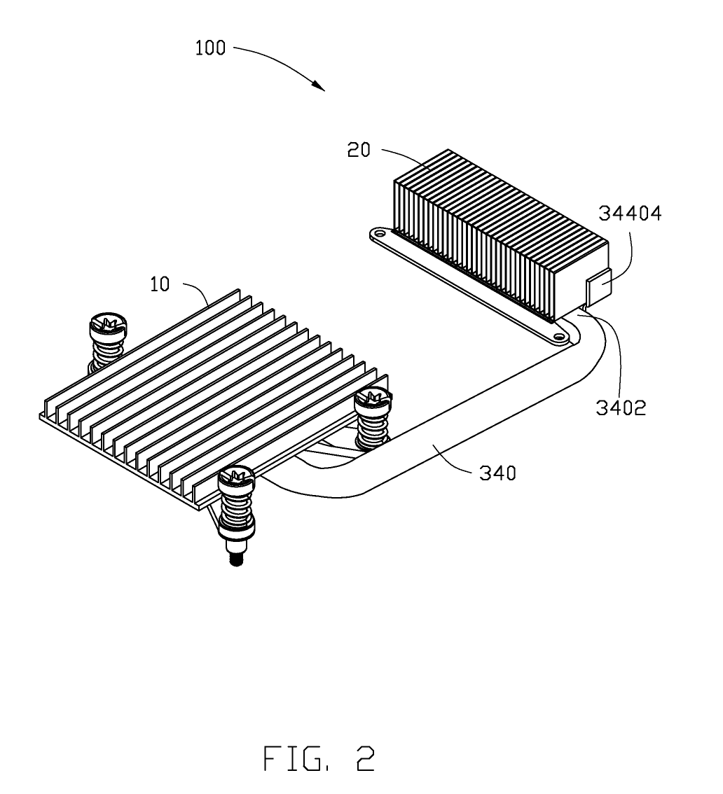

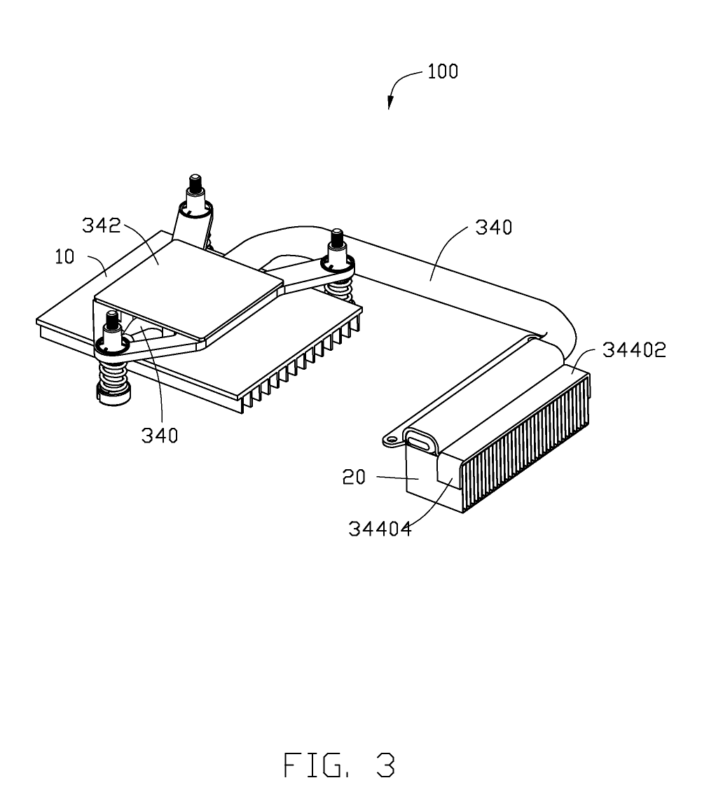

FIGS. 2 and 3 illustrate when the heat dissipation device 100 is assembled, one of the two pipes 3402 is received in the slot 3202 of the first heat conduction member 32. The heat exchanging plate 342 is engaged with the body 340 and the plate 320. The first heat dissipation member 10 is located on the plane 3204 of the first heat conduction member 32. The other pipe 3402 is received in the groove 3440 of the connecting member 344. A top surface of the one of the two pipes 3402 and the mounting plate 34402 are substantially aligned in a same plane. The second heat dissipation member 20 is engaged with the mounting plate 34402 and the two stopper plates 34404. The second heat dissipation member 20 contacts one of the two pipes 3402.

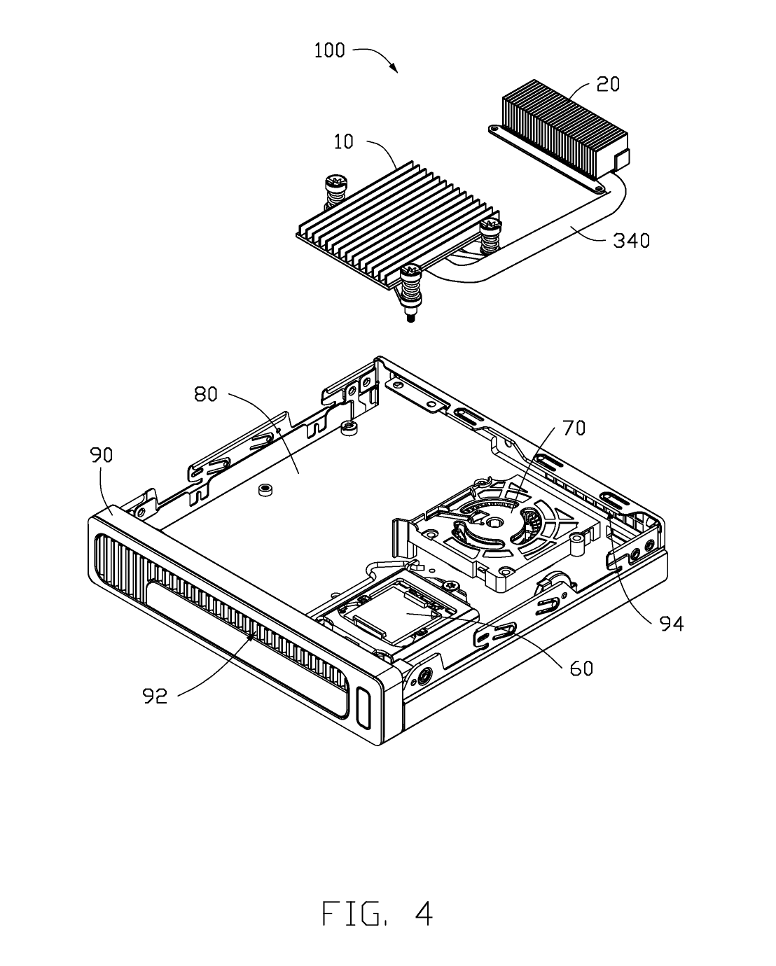

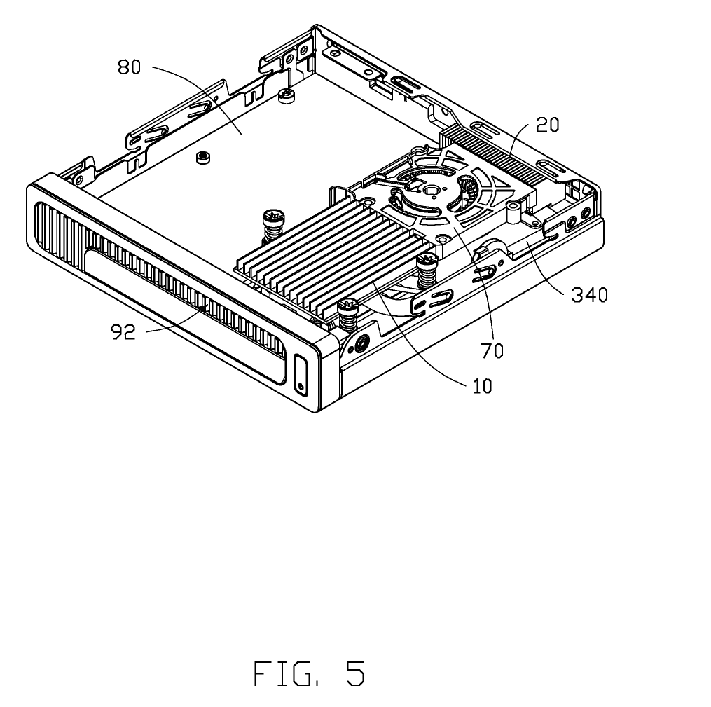

FIGS. 4 and 5 illustrate the heat dissipation device 100 in use. The heat exchanging plate 342 is engaged with a heating element 60. Each screw 40 is engaged with each hole 3220 to secure the first heat conduction member 32 to a motherboard 80. Heat from the heating element 60 is transferred to the first heat dissipation member 10 by the heat exchanging plate 342. The first heat dissipation member 10 is located on one side of an air inlet 92 of a chassis 90. A fan 70 is located between the first heat dissipation member 10 and the second heat dissipation member 20. The second heat dissipation member 20 is located on one side of an air outlet 94 of the chassis 90.

Heat from the heating element 60 is transferred to the body 340 and the first heat conduction member 32 by the heat exchanging plate 342. The first heat conduction member 32 transfers the heat to the first heat dissipation member 10. Air from the air inlet 92 cools the dissipation member 10. The heat is transferred from one pipe 3402 located in the slot 3202 to the other pipe 3402 located in the groove 3440. The connecting member 344 and the pipe 3402 located in the groove 3440 transfer the heat to the second heat dissipation member 20. The fan 70 dissipates heat from the second heat dissipation member 20 out of the chassis 90 through the air outlet 94.

FIGS. 4 and 5 also illustrate one embodiment of a heat dissipation system.

The embodiments shown and described above are only examples. Many details are often found in the art such as the other features of a heat dissipation device. Therefore, many such details are neither shown nor described. Even though numerous characteristics and advantages of the present technology have been set forth in the foregoing description, together with details of the structure and function of the present disclosure, the disclosure is illustrative only, and changes may be made in the details, especially in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A heat dissipation device comprising:
a first heat dissipation member;
a second heat dissipation member; and
a heat conduction member substantially U-shaped;
wherein the first heat dissipation member and the second heat dissipation member are located on two parallel ends of the heat conduction member, one of the two ends of the heat conduction member is configured to be engaged with a heating element, and the heat conduction member is configured to transfer heat to the first heat dissipation member and the second heat dissipation member.

2. The heat dissipation device of claim 1, wherein the heat conduction member comprises a first heat conduction member and a second heat conduction member, the first heat conduction member comprises a plate, the plate defines a slot, the second heat conduction member comprises a body, and one end of the body is received in the slot.

3. The heat dissipation device of claim 2, wherein the second heat conduction member further comprises a heat exchanging plate, the heat exchanging plate is configured to be engaged with the heating element, and the body and the plate are engaged with the heating element.

4. The heat dissipation device of claim 2, wherein the second heat conduction member further comprises a connecting member, the connecting member defines a groove, and the other end of the body is configured to receive in the groove.

5. The heat dissipation device of claim 4, wherein the connecting member comprises a mounting plate and two stopper plates, and the two stopper plates are located on the two opposite ends of the mounting plate.

6. The heat dissipation device of claim 5, wherein the two stopper plates are substantially parallel to each other.

7. The heat dissipation device of claim 6, wherein each stopper plate is substantially perpendicular to the mounting plate.

8. The heat dissipation device of claim 5, wherein the body comprises two pipes, a top surface of the one of the two pipes and the mounting plate are substantially aligned in a same plane, and the second heat dissipation member is engaged with the mounting plate, the two stopper plates, and the one of the two pipes.

9. The heat dissipation device of claim 2, the heat dissipation device further comprising at least one screw, wherein the first heat conduction member comprises at least one fixing portion, the at least one fixing portion defines a hole, and the at least one screw is configured to engage with each hole to secure the first heat conduction member.

10. A heat dissipation system comprising:
a fan;
a first heat dissipation member;
a second heat dissipation member; and
a heat conduction member;
wherein the first heat dissipation member and the second heat dissipation member are located on two ends of the heat conduction member, the fan is located between the first heat dissipation member and the second heat dissipation member, the one of the two ends of the heat conduction member is configured to be engaged with a heating element, the heat conduction member is configured to transfer heat to the first heat dissipation member and the second heat dissipation member, and the fan cools the first heat dissipation member and the second heat dissipation member.

11. The heat dissipation system of claim 10, wherein the heat conduction member is substantially U-shaped, and the two ends of the heat conduction member is parallel to each other.

12. The heat dissipation system of claim 10, wherein the heat conduction member comprises a first heat conduction member and a second heat conduction member, the first heat conduction member comprise a plate, the plate defines a slot, the second heat conduction member comprise a body, and one end of the body is received in the slot.

13. The heat dissipation system of claim 12, wherein the second heat conduction member further comprises a heat exchanging plate, the heat exchanging plate is configured to be engaged with the heating element, and the body and the plate are engaged with the heating element.

14. The heat dissipation system of claim 12, wherein the second heat conduction member further comprises a connecting member, the connecting member defines a groove, and the other end of the body is configured to receive in the groove.

15. The heat dissipation system of claim 14, wherein the connecting member comprises a mounting plate and two stopper plates, and the two stopper plates are located on the two opposite ends of the mounting plate.

16. The heat dissipation system of claim 15, wherein the two stopper plates are substantially parallel to each other.

17. The heat dissipation system of claim 16, wherein each stopper plate is substantially perpendicular to the mounting plate.

18. The heat dissipation system of claim 15, wherein the body comprises two pipes, a top surface of the one of the two pipes and the mounting plate are substantially aligned in a same plane, and the second heat dissipation member is engaged with the mounting plate, the two stopper plates, and the one of the two pipes.

19. The heat dissipation system of claim 12, the heat dissipation system further comprising at least one screw, wherein the first heat conduction member comprises at least one fixing portion, the at least one fixing portion defines a hole, and the at least one screw is configured to engage with the hole to secure the first heat conduction member.
